(19) United States
(12) Patent Application Publication
(10) Pub. No.: US 2007/0262363 A1
(43) Pub. Date: Nov. 15, 2007

(54) Low temperature fabrication of discrete silicon-containing substrates and devices

(75) Inventors: Meng Tao, Colleyville, TX (US); Fang Shi, Boise, ID (US)

Correspondence Address: MONIQUE A. VANDER MOLEN;GARDERE WYNNE SEWELL LLP, 3000 THANKSGIVING TOWER, 1601 ELM ST, SUITE 3000, DALLAS, TX, 75201, US

(73) Assignee: BOARD OF REGENTS, UNIVERSITY OF TEXAS SYSTEM, Austin, TX (US)

(21) Appl. No.: 11/788,227

(22) Filed: Apr. 19, 2007

Related U.S. Application Data
(63) Continuation-in-part of application No. 11/507,223, filed on Aug. 21, 2006.
(63) Continuation-in-part of application No. 11/360,139, filed on Feb. 23, 2006.
(63) Continuation-in-part of application No. 10/822,343, filed on Apr. 12, 2004.
(63) Continuation-in-part of application No. 10/377,015, filed on Feb. 28, 2003, now Pat. No. 6,784,114.
(60) Provisional application No. 60/655,383, filed on Feb. 23, 2005.

(51) Int. Cl. H01L 29/78; H01L 21/20; H01L 21/336

(52) U.S. Cl. 257/288; 438/197; 438/478; 257/E21.09; 257/E29.255; 257/E21.409

(57) ABSTRACT

Fabrication methods and processes are described, the methods and processes occurring at a low-temperature and involving passivation. The methods and processes easily incorporate annealing, deposition, patterning, lithography, etching, oxidation, epitaxy and chemical mechanical polishing for forming suitable devices, such as diodes and MOSFETs. Such fabrication is a suitable and more cost-effective alternative to a process of diffusion or doping, typical for forming p-n junctions. The process flow does not require temperatures above 700 degrees Centigrade. Formation of p-n junctions in discrete silicon diodes and MOSFETs are also provided, fabricated at low temperatures in the absence of diffusion or doping.

### CROSS-REFERENCES TO RELATED APPLICATION

This application is a continuation-in-part of U.S. patent application Ser. No. 11/507,223 filed Aug. 21, 2006, which is a continuation-in-part of U.S. patent application Ser. No. 11/360,139, filed Feb. 23, 2006, which claims the benefit of Provisional Application No. 60/655,383 filed Feb. 23, 2005, and is a continuation in part of U.S. patent application Ser. No. 10/822,343 having a filing date of Apr. 12, 2004, which claims the benefit of and is a continuation-in-part of U.S. patent application Ser. No. 10/377,015 filed Feb. 28, 2003, now issued as U.S. Pat. No. 6,784,114. Such applications and patents are incorporated herein by reference.

### STATEMENT REGARDING FEDERALLY SPONSORED RESEARCH OR DEVELOPMENT

The U.S. Government has a paid-up license in this invention and the right in limited circumstances to require the patent owner to license others on reasonable terms as provided for by the terms of Grant Nos. 0322762 and 0620319 awarded by The National Science Foundation.

### BACKGROUND OF THE INVENTION

The invention described relates generally to the field of semiconductor surface engineering and in particular to substrates, devices and methods for preparing such substrates and devices, the fabrication methods capable of modifying a surface of a semiconductor substrate comprising silicon as well as reducing energy consumption during fabrication.

Energy consumption in the semiconductor industry remains extremely high. The discrete silicon diode and metal-oxide-semiconductor field-effect transistor (MOSFET) markets, together, were about a $10 billion (USD) industry worldwide in 2005 and estimated to grow to about $15-billion in 2010. For discrete devices, a large portion of the manufacturing cost comes from high-temperature and time-consuming processes such as diffusion and/or doping. Accordingly, there remains a need to adopt energy saving methods for fabrication of semiconductor substrates and devices, such methods that are sure to provide cost savings as well as financial incentives to semiconductor manufacturers.

### SUMMARY OF THE INVENTION

The invention described overcomes one or more disadvantages described and associated with many current semiconductor and device fabrication methods. For example, as provided herein are methods for fabricating discrete silicon-containing substrates and devices, including diodes and MOSFETs, fabrication that is more cost effective and energy efficient.

Fabrication methods and processes described herein occur at a low-temperature and include a passivation process. Fabrication easily incorporates annealing, deposition, patterning, lithography, etching, oxidation, epitaxy and chemical mechanical polishing for forming suitable devices, such as diodes and MOSFETS. Such fabrication is a more cost-effective alternative to a process of diffusion or doping, typical for forming p-n junctions. Whereas diffusion requires temperatures at about 1000° C. for up to several hours, fabrication herein may occur at temperatures below 1000° C., preferably below 700° C. and for less time and money.

Formation of p-n junctions in discrete silicon diodes and MOSFETs are described herein, fabricated in the absence of diffusion or doping. Formation occurs by incorporating a low temperature passivation process described herein. Formation may be further integrated with other methods, such as low temperature oxidation and low temperature epitaxy to provide further cost and energy savings. Energy consumption is reduced with the low temperature fabrication processes described herein; energy consumption may be reduced as much as two orders of magnitude, as compared with conventional processes.

Devices fabricated from such methods comprise a semiconductor material in which one or more p-n junctions are formed after passivation of a surface of the semiconductor material and a region of the passivated surface is modified from one semiconductor conduction type to another conduction type. The region herein is a portion of the surface under a deposited metal. When the semiconductor conduction type is p-type, one or more n-type regions are formed on the surface after providing a low work-function metal. When the semiconductor conduction type is n-type, one or more p-type regions are formed on the surface after providing a high work-function metal.

Those skilled in the art will further appreciate the above-noted features and advantages of the invention together with other important aspects thereof upon reading the detailed description that follows in conjunction with the drawings.

### BRIEF DESCRIPTION OF THE FIGURES

For more complete understanding of the features and advantages of the present invention, reference is now made to the detailed description of the invention along with the accompanying figures, wherein:

FIGS. 1A and 1B depict representative schematics of atomic structures of a nascent silicon (100) surface with (A) side view into the [011] direction and (B) top view into the [100] direction, wherein dark circles are surface atoms, open circles are second-layer atoms, third, fourth, and fifth layer atoms are gray circles, and wherein each surface atom has two dangling bonds;

FIG. 2 depicts representative schematics of atomic structures of a passivated silicon (100) surface with a monolayer of a passivant in (A) side view into the [011] direction and (B) top view into the [100] direction, wherein hatched circles represent the passivating atoms and the passivated surface has no dangling bond;

FIGS. 3A and 3B depict band diagrams for formation of p-n junctions as described herein free of doping, wherein (A) represents a low work-function metal on a valence-mended p-type silicon (100) surface and (B) represents a high work-function metal on a valence-mended n-type silicon (100) surface;

FIG. 4 depicts a current-voltage relationship at room temperature for a passivated low work function metal/p-type silicon diode as compared with a non-passivated/low work function metal/p-type silicon diode;

FIG. 5 depicts in a logarithmic plot, a current-voltage relationship at room temperature for a low work function metal/passivated p-type silicon diode as compared with a non-passivated/low work function metal/p-type silicon diode;

FIGS. 6A-6D schematically illustrate a representative low-temperature process flow described herein for fabricating discrete silicon p-n junction diodes;

FIG. 7 depicts schematically a cross section of a representative n-channel MOSFET fabricated with a low-temperature method described herein;

FIGS. 8A-8E schematically illustrate a representative low-temperature process flow for fabricating discrete n-channel silicon MOSFETs;

FIG. 9 depicts schematically a top view of a representative n-channel MOSFET fabricated with the low-temperature process flow as may be depicted in FIG. 8; and

FIGS. 10A-10E depict schematically another representative low-temperature process flow for fabricating discrete n-channel silicon MOSFETs.

### DETAILED DESCRIPTION OF THE INVENTION

The invention, as defined by the claims, may be better understood by reference to the following detailed description. The description is meant to be read with reference to the figures contained herein. This detailed description relates to examples of the claimed subject matter for illustrative purposes, and is in no way meant to limit the scope of the invention. The specific aspects and embodiments discussed herein are merely illustrative of ways to make and use the invention, and do not limit the scope of the invention.

Dangling bonds and strained bonds are an inherent nature of semiconductor surfaces. Dangling and strained bonds cause a variety of problems in the fabrication of solid-state devices on semiconductor substrates. They are responsible for the high chemical reactivity of the surface by acting as reaction sites for chemical reactions and create surface states that cause the observed properties of electronic devices to vary from their design specifications. On a semiconductor surface, dangling bonds adsorb oxygen, water, or carbon dioxide, and on the surface of silicon, a layer of silicon (Si) dioxide (the so-called “native oxide”) is formed as soon as the surface is exposed to air. Dangling bonds may be alleviated by passivating the surface with a passivating agent.

One advantage, as described herein, is that a passivation layer formed by a passivating agent is thin enough (often about one Angstrom thick) that a semiconductor surface still provides semiconducting behaviors. Examples of silicon-based semiconductor materials include silicon-germanium alloys, and silicon carbide.

As presented herein, passivation is a monolayer effect that saturates dangling bonds and relaxes strained bonds on a semiconductor surface such that the surface becomes much less reactive chemically. Thus, when a passivated semiconductor surface provided herein is in contact with various reactants (e.g., oxygen, water vapor, metals, metal oxides, dielectrics, as examples), there is a suppression of such potential reactants from actually reacting with the semiconductor surface.

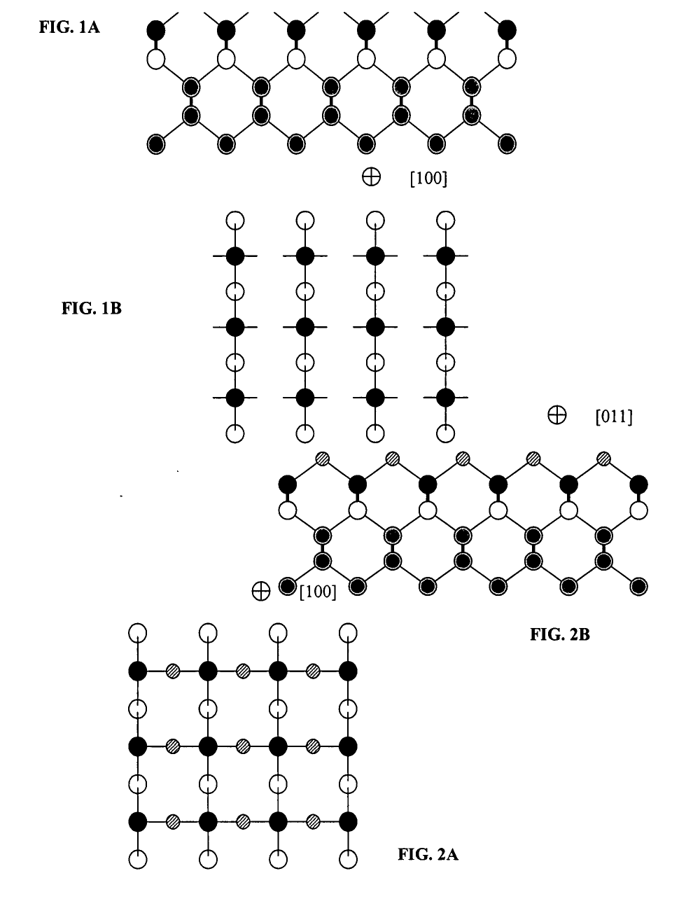

In one form, a semiconductor surface is where chemical bonds are broken and dangling bonds are created. For example, each surface atom on a (100) surface comprising silicon has two dangling bonds, as shown in FIG. 1A and B, which make the surface electrically and chemically reactive. When the surface is exposed to air, the dangling bonds quickly react with air and chemically adsorb molecules or species from the air, such as water, carbon dioxide, oxygen, as examples. When the surface is in contact with other materials such as metals or metal oxides, interfacial reactions take place, which form an interfacial layer of silicide or oxide with or without heating.

Electrically, surface states originate from dangling bonds and strained surface bonds and often pin the surface Fermi level, causing surface band bending. When a second layer (e.g., metal) is deposited on the silicon (100) surface, surface states (now more appropriately, interface states) pin the interface Fermi level, making the Schottky barrier height less dependent on the second layer work function and silicon electron affinity, and instead, the barrier height is controlled by surface states and/or the pinned interface Fermi-level.

To eliminate dangling bonds on a semiconductor surface, a surface modification may be provided in which a very thin layer of what may be referred to as valence-mending atoms are positioned on the surface, as depicted, as an example, in FIG. 2. In one embodiment, a thin layer of valence mending atoms are positioned, wherein the layer of atoms is one atomic layer thick. For the silicon (100) surface as described above, valence-mending atoms include Group VI elements and congeners, such as sulfur, selenium, and tellurium. The atomic structure of a valence-mended silicon (100) surface is represented in FIG. 2A and 2B.

The concept of valence-mending was proposed to modify the semiconductor surface, e.g., by eliminating dangling bonds on the surface and/or reducing (deactivating) surface states. For a silicon (100) surface, valence-mending atoms may bridge between two surface atoms, thereby terminating or eliminating dangling bonds and relaxing strained bonds on the surface. Examples of valence-mending atoms for silicon-based surfaces [e.g., silicon(100)] include Group VI elements and congeners, such as S, Se and Te. Such elements may be used to passivate a surface of a semiconductor by bridging between surface atoms and eliminating dangling bonds. For other morphologies such as atomic steps on a semiconductor surface, monovalent elements such as halogens of Group VII elements or hydrogen and its isotopes may be used to valence mend and passivate those areas of the semiconductor surface.

Typically, when a layer of metal or dielectric is deposited onto a semiconductor surface, interfacial reactions occur and a compound layer (e.g., silicide when the semiconductor surface is silicon) forms between metal/dielectric and the semiconductor surface. The compound layer may form with and without heating, often depending on the reactivity of the particular metal/dielectric-semiconductor pair. As described herein, when a layer of metal or dielectric is deposited onto a valence-mended semiconductor surface, interfacial reactions are suppressed up to a higher temperature and no compound layer is formed below that temperature.

Deposited metals may include, but are not limited to, high work function metals, low work function metals, and others, examples of which include but are not limited to aluminum. titanium, cobalt, nickel, tungsten, molybdenum, platinum, gold, and chromium, and metals commonly used in semiconductor devices. As described, when such metals are in contact with silicon, silicides of different phases and different stoichiometries are typically formed at the interface (with or without heating). By passivating the semiconductor surface with the methods described herein before placing the surface in contact with a metal, interfacial silicide formation is suppressed.

In one or more embodiments are provided processes in which a surface of a semiconductor substrate or silicon-containing substrate is passivated without substantially altering the property of the underlying material. Passivation of semiconductor and silicon surfaces described herein may be realized by traditional methods, such as chemical vapor deposition, physical vapor deposition or by other methods such as wet chemical passivation. In a wet chemical process, passivation occurs in a liquid, the oxide of silicon does not dissolve in the liquid and the liquid itself may act as a suitable etching and/or cleaning agent of the semiconductor surface (e.g., to further remove native oxide and/or purposely grown or deposited oxide and/or further remove additional contaminants from the substrate surface).

The thickness of the passivation layer provided herein is preferably only one atomic layer (e.g., a few angstroms) and is not thick enough that a passivated surface no longer behaves as a semiconducting surface but an insulating one. Passivation modifies the substrate surface and/or reduces interfacial reactions without substantially altering properties of the underlying substrate. A substrate prepared in a manner described herein provides for substrates and solid-state devices that have greatly lowered Schottky barriers for improved ohmic contact and/or greatly raised Schottky barriers for other preferred device functionalities.

Examples of useful passivating agents for a surface of silicon-based semiconductor [including (100), (110), (111) surfaces] include sulfur (S), selenium (Se) and tellurium (Te). In liquid, such passivants may be provided as a solution, examples of which include ammonium sulfide [(NH₄)₂S], ammonium selenide [(NH₄)₂Se], and sulfur chloride [S₂Cl₂], to name a few. Suitable etching agents (e.g., compatible with and do not react or cross-react with a passivating agent), include solutions of ammonium (e.g., ammonium hydroxide [NH₄OH], ammonium fluoride [NH₄F], and ammonium chloride [NH₄Cl]) and solutions further comprising chloride (Cl). Such etching agents may be provided in solution as appropriate for etching as is known to one of ordinary skill in the art.

As further described herein, low-temperature fabrication methods for silicon- and semiconductor surfaces and discrete silicon devices (e.g., diodes and MOSFETs) are provided. The low-temperature processes applied to silicon and semiconductor surfaces and/or discrete devices provide a suitable alternative to diffusion or doping that require high temperatures. Such high temperature processes (e.g., diffusion, oxidation, annealing, and epitaxy) typically involve temperatures of at least about 1000° C., that may be applied for up to several hours.

Diffusion and annealing, for example, are typically performed for the purpose of doping, which is required to control electrical properties of silicon or a semiconductor surface for device operation and performance. As an example, a p-n junction is formed when a p-type dopant, such as boron, is introduced into an n-type silicon wafer. For diffusion of the dopant, a high temperature and long processing time are required to allow the dopant to reach a desired depth on the silicon wafer. A high-temperature annealing step is often required to activate the implanted dopant and repair implantation-induced lattice damage. The atomistic mechanisms involved in diffusion and annealing set the minimum temperature required for these processes. To date, there appear to be no low-temperature alternatives to diffusion or annealing.

In one or more embodiments, described herein include methods and means for forming p-n junctions in silicon-containing substrates in the absence of doping. As such, fabrication does not require diffusion or ion implantation followed by annealing; the high temperatures typically required for diffusion and annealing are no longer required. Moreover, when integrated with low-temperature processes for oxidation and epitaxy, a maximum temperature required for fabrication of a semiconductor substrate and/or discrete silicon-containing device (e.g., diode and MOSFET) is reduced from at or greater than 1000° C. to below 700° C.

Because energy consumption is, in principle, proportional to the absolute temperature quadrupled (∝ T⁴), by reducing the process temperature from 1000° C. to 700° C., energy consumption as provided with methods and processes described herein is reduced by at least two fold.

As described herein, an atomic structure of a surface of a silicon-containing substrate is engineered. While a silicon (100) surface is a surface of choice for typical commercial discrete silicon devices, the principles and methods described here may also be applied to other silicon-containing surfaces, such as (110) or (111) surface.

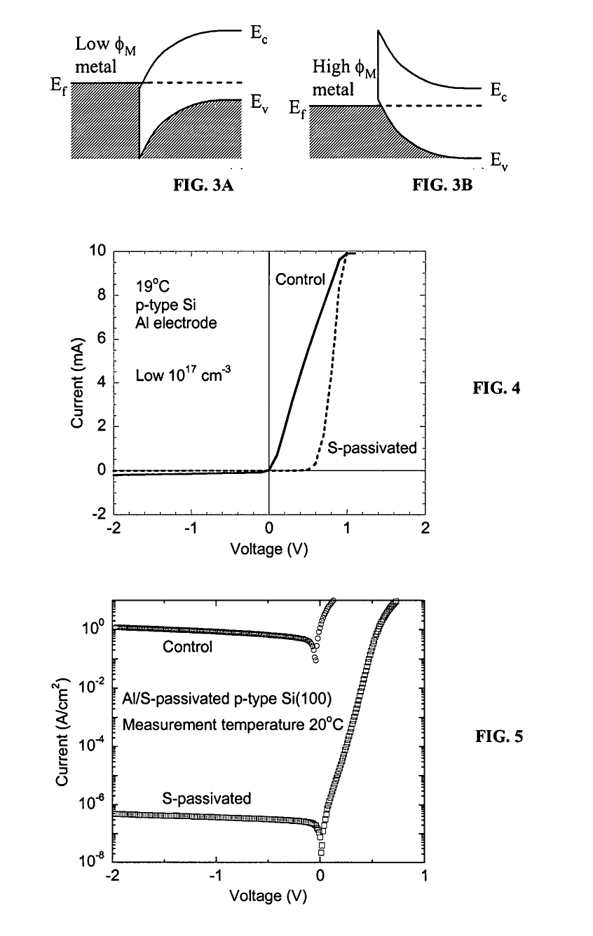

Using a silicon (100) surface as an example, a single atomic layer of a passivating agent (e.g., sulfur or selenium or tellurium) is deposited on the surface to terminate dangling bonds and create a silicon (100) surface with few dangling bonds. Such a silicon (100) surface is also referred to as a valence-mended silicon (100) surface. Described herein, to form a p-n junction on a p-type valence-mended silicon (100) surface, a metal with a low work function (φ_{M}) is further deposited on a modified silicon surface (e.g., aluminum, titanium, vanadium, zinc, silver, as examples including equivalents as known to one of ordinary skill in the art). According to the Schottky-Mott theory, the Schottky barrier height for electrons (Φ_{Bn}) is given by Φ_{Bn}=φ_{M}−χ_{S}, where χ_{S} is the electron affinity of the semiconductor, in this case silicon. If the metal work function in the equation is small enough as compared to the silicon electron affinity, the Schottky barrier height becomes small enough and even negative. Thus, by applying a metal with a low work function, the surface of the p-type silicon wafer becomes n-type and a p-n junction is thus formed in the absence of doping. The low work-function metal may be considered an electrical contact to the n-side of the formed p-n junction. The metal/p-type silicon structure behaves like a p-n junction. FIG. 3A shows a representative band diagrams for the p-n junction formed by a method described herein absent.

Schottky barrier heights of various metals on n- and p-type silicon (100) surface are known to one of ordinary skill. They typically fall in the range of 0.4-0.7 eV. Methods have been attempted to increase and decrease the barrier height, and most of them concern silicon surface treatment or metal/silicon interface treatments, such as deep surface cleaning, hydrogen passivation, ion implantation, growth of thin silicon oxide layer, and silicidation of interface. Most methods have not been successful.

As further described herein, to form a p-n junction on an n-type valence-mended silicon (100) surface, a metal with a high work function is deposited on a modified silicon surface (e.g., nickel, palladium, gold, platinum, as examples, including equivalents as known to one of ordinary skill in the art). The Schottky barrier height for holes (Φ_{Bp}) is given by Φ_{Bp}=χ_{S}+E_{g}−φ_{M}, where E_{g} is the band gap of silicon. With a large work-function metal, the Schottky barrier height becomes small enough and even negative. Thus, the surface of an n-type silicon wafer becomes p-type and a p-n junction is formed without doping. The high work-function metal may be considered an electrical contact to the p-side of this formed p-n junction. The metal/n-type silicon structure behaves like a p-n junction. FIG. 3B illustrates the band diagram for this p-n junction formation absent doping.

Several features of the above fabrication methods are disclosed. Typically, a single atomic layer of a passivating agent (e.g., sulfur, selenium or tellurium) is deposited on the surface of silicon-containing substrate [e.g., (100) surface, (110) surface, (111) surface], such that dangling bonds on the silicon surface are largely terminated. For an n-type surface passivated with an atomic layer of a passivating agent, a film of a metal with a large work function is deposited on the surface. For a p-type surface passivated with an atomic layer of a passivating agent, a film of a metal with a small work function is deposited on the surface.

No diffusion or ion implantation is involved in fabrication of metal/silicon structures described herein. Accordingly, no high-temperature process is required in fabrication of the surfaces and junctions described. Such metal/silicon structures are further incorporated as p-n junctions into discrete silicon devices, including diodes and MOSFETs. The fabrications processes described may be fully integrated with other low-temperature processes for epitaxy and oxidation, as examples, to provide new process flows for low-temperature manufacturing of silicon-containing surfaces and substrates as well as discrete silicon devices, such as diodes and MOSFETs.

In another example, a high Schottky barrier for holes between a thin metal layer and a passivated p-type silicon surface was provided. Capacitance-voltage measurements indicated a barrier height of 1.1 eV; activation-energy measurements suggested 0.94-0.97 eV. The barrier height of 1.1 eV further suggested degenerate inversion on the p-type silicon surface, and Fermi statistics, instead of Boltzmann statistics, was used to describe the electrostatics. Temperature-dependent current-voltage measurements showed that passivation reduced the reverse saturation current of aluminum/p-type silicon (100) diodes by over six orders of magnitude.

For the above-described, two identical p-type silicon (100) wafer sets were prepared. Each wafer set had a boron doping level of low 10¹⁷ cm⁻³. One wafer set was cleaned in hydrofluoride (HF) but without passivation and served as controls. The other set was first cleaned in HF and then oxidized in ozone to form a 2-nm oxide layer. These wafers were passivated with an atomic layer of sulfur. The oxide layer was stripped and the wafers were wet-chemically passivated in an aqueous solution of ammonium sulfide. Alternative passivating agents, such as selenium or tellurium are suitable as replacements and may be provided in suitable liquids of ammonium, chloride, or the like. Passivation was realized by submerging the silicon wafers into an aqueous solution containing ammonium sulfide (NH₄)₂S and ammonium hydroxide (NH₄OH). The concentration of (NH₄)₂S was 1 M, and the concentration of NH₄OH was 2.4 M. The solution temperature was 60° C., and passivation time was about 24 minutes. On both wafer sets, circular low work-function aluminum electrodes with a diameter of 216 μm and thickness of about 100 nm were formed by evaporation through a shadow mask. Electrical contacts to the back side of each wafer were fabricated by depositing an aluminum film on the entire back side. The large area of the back contact made it possible to characterize the front aluminum/silicon structures with a negligible effect from the Schottky behavior of the back contact. Capacitance-voltage, current-voltage, and activation energy measurements were made to characterize the aluminum/p-type silicon structures formed on each wafer.

Measurements of passivated and control wafers demonstrated that the formed aluminum/p-type silicon structures behaved as p-n junction diodes, as reported by the inventors in Song, et al. IEEE Electron Device Letters, 2007;28:71 (discussion and data incorporated herein by reference). FIG. 4 shows the current-voltage relationship of the aluminum/sulfur-passivated p-type silicon (100) structure as compared with the aluminum/non-passivated p-type silicon (100) structure. The passivated structure had a turn-on voltage of about 0.6 V, just like a typical silicon p-n junction. FIG. 5 shows the current-voltage characteristics of the aluminum/sulfur-passivated p-type silicon (100) structure as compared to the aluminum/p-type silicon (100) structure without sulfur passivation in a semi-logarithmic plot. With sulfur passivation, the forward current-voltage relation is linear over eight orders of magnitude and the reverse saturation current is reduced by over six orders of magnitude. The significant reduction in reverse current is a result of an at least about 0.5-eV increase in barrier height by passivation. All these results are characteristic of a silicon p-n junction.

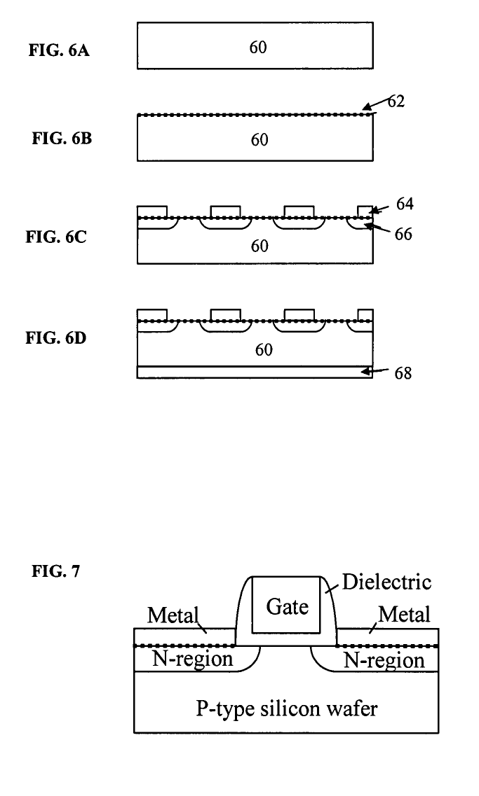

FIG. 6 shows schematically an example of at least one representative process flow for fabricating silicon p-n junction diodes. This process does not involve diffusion or ion implantation, therefore the maximum temperature for the process is significantly reduced over traditional processes. Referring to FIG. 6, p-n junctions are formed by preparing one or more n-type regions on a surface of a p-type silicon-containing substrate by providing a low work-function metal after passivation. Shown in FIG. 6A is a p-type silicon (100) substrate (60) having a top and bottom surface. The substrate here and for all examples provided herein may be any silicon-containing substrate having at least one silicon surface. Shown in FIG. 6B, is passivation (e.g., with a single atomic layer) with a passivating agent (62) on a top surface of substrate 60 after suitable cleaning. Shown in FIG. 6C, one or more low work-function metallic electrodes 64 are provided on the passivated surface by a suitable means, e.g., lithographic patterning or deposition through a shadow mask, as examples. Examples of suitable low work-function metals for p-type silicon include aluminum, titanium, vanadium, zinc, silver, and others known to one of ordinary skill in the art. Portions under the low work-function metal electrodes 64 are turned into n-type regions 66. In FIG. 6D, for back side ohmic contact, a suitable metal 68 (e.g., as a film) having a low Schottky barrier on p-type silicon, may be deposited. Suitable metals for the ohmic contact includes nickel, platinum, tungsten, and others known to one of ordinary skill in the art. The formed structure may be further processed as desired, such as undergoing annealing for formation of a silicide on the bottom surface of the substrate. The formed structure is then ready for dicing, packaging, testing and use.

For n-type silicon-containing substrates, a process flow as described with FIG. 6 is further modified as follows. After passivation, one or more high work-function metallic electrodes are fabricated on the passivated surface (e.g., by lithographic patterning, deposition through a shadow mask, as examples). Suitable examples of high work-function metals for n-type silicon include nickel, palladium, gold, platinum, and others known to one of ordinary skill in the art. Portions under the high work-function metal are turned into p-type regions. For back side ohmic contact, a second or suitable metal with a low Schottky barrier on n-type silicon is deposited. Suitable metals include titanium and others known to one of ordinary skill in the art. The formed structure may be further processed as desired, such as undergoing annealing for formation of a silicide on the bottom surface of the substrate. The formed structure is then ready for dicing, packaging, testing and use.

MOSFETs, including both n-channel MOSFETs and p-channel MOSFETs, may also be fabricated as described herein. FIG. 7 shows schematically the cross section of a n-channel MOSFET fabricated in accordance with methods described herein. Features of n-channel MOSFETs described herein include a starting substrate that is a p-type silicon-containing wafer/substrate and surface areas for the source and drain that are passivated with at least one atomic layer of a passivating agent. With such MOSFETs, there is no doping (e.g., no diffusion or ion implantation) when forming the source and drain regions. In addition, one or more low work-function metals (e.g., aluminum, titanium, vanadium, zinc, silver) are deposited over the passivated surface areas of the source and drain. With this process, the source and drain regions are turned into n-type by the low work function of the deposited metal.

A p-channel MOSFET is similarly fabricated as described above in which features of p-channel MOSFETs include a starting substrate that is a n-type silicon-containing wafer/substrate and surface areas for the source and drain that are passivated with at least one atomic layer of a passivating agent. With such MOSFETs, there is no doping (e.g., no diffusion or ion implantation) when forming the source and drain regions. In addition, one or more high work-function metals (e.g., nickel, palladium, gold, platinum) are deposited over the passivated surface areas of the source and drain. With this process, the source and drain regions are turned into p-type by the high work function of the deposited metal.

Formation of the source and drain regions described herein does not involve diffusion or ion implantation, therefore the maximum temperature in the process is significantly reduced as compared with their formation using more traditional and/or conventional processes. They are formed by turning the source and drain regions into the opposite conduction type with a properly chosen metal having a suitable work function.

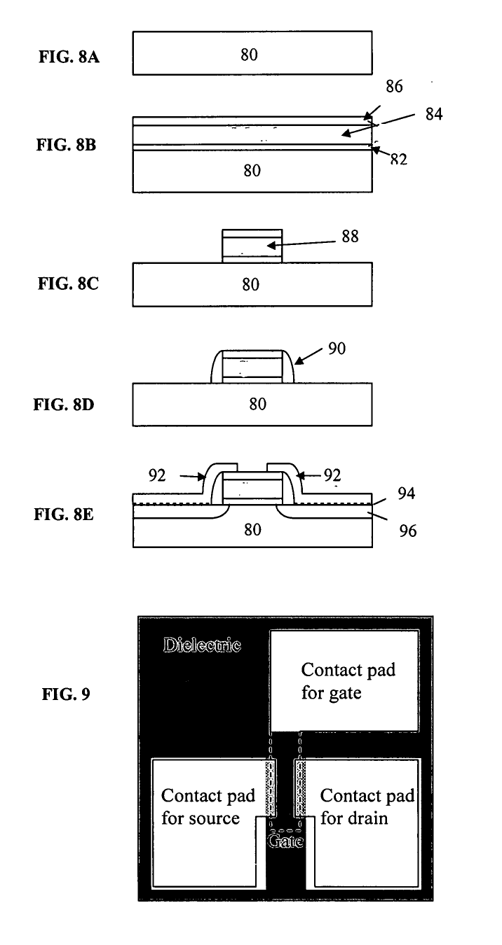

FIG. 8 provides schematically a suitable and representative process flow for fabricating a silicon-containing n-channel MOSFET. With this process, a low-temperature oxidation process using ozone may be incorporated, thereby reducing the maximum temperature for the process flow to below 700° C. As illustrated in FIG. 8A, an initial substrate 80 is provided as a p-type silicon-containing substrate/wafer or other suitable form having a top surface and a bottom surface. After cleaning, the top surface of substrate 80 is oxidized in ozone to form a layer of silicon dioxide 82 (FIG. 8B). The temperature of the oxidation process is typically below 700° C. by using ozone oxidation. A metal having a desired and proper work function is deposited on top of the silicon dioxide layer as film 84 (FIG. 8B). The work function of the metal determines the threshold voltage required to turn on the n-channel MOSFET. A suitable dielectric layer 86, such as silicon dioxide or silicon nitride, is deposited on top of film 84 (FIG. 8B). The tri-layer 82/84/86 is patterned by lithography to form gate 88 for the n-channel MOSFET (FIG. 8C). The dielectric layer on top of the gate is purposely left in place. Another layer of a dielectric 90, such as silicon dioxide or silicon nitride, as examples, is deposited over the wafer. By anisotropic etching, this layer of dielectric is etched away, except at the two sides of the gate to form spacers (FIG. 8D). The top of the gate is still covered by a dielectric layer, but the surface areas of the source and drain are exposed. After proper cleaning, the surface areas of the source and drain are passivated with at least one atomic layer of a passivating agent 94 (e.g., sulfur, selenium or tellurium). A film of a metal 92 with a low work function is deposited over the entire wafer. As before, suitable low work-function metals for p-type silicon include aluminum, titanium, vanadium, zinc, silver, as examples. The metal film 92 is patterned (e.g., through lithography and etching) to form the source and drain electrodes (FIG. 8E). A region under the passivated portions formed by agent 94 becomes a n-type region 96. The electrical contact to the gate region is made through a contact pad, an example of this is depicted in FIG. 9. The gate of the MOSFET is covered with a dielectric layer to electrically insulate the gate from the source and drain. The final structure may go through one or more additional annealing steps as desired. Upon completion, the structure is ready for dicing, packaging, testing and use.

In FIG. 9, electrical contact to a gate is made through a contact pad, over which a dielectric layer is removed. The dielectric layer is also removed over the source and drain regions. The exposed source and drain regions are passivated with an atomic layer of sulfur or selenium or tellurium and then a low work-function metal is deposited over the source and drain regions.

For p-channel MOSFETs, a process flow as depicted in FIG. 8 is modified so that the initial substrate is a n-type silicon-containing wafer/substrate or suitable surface. The n-type substrate is cleaned and oxidized in ozone to form a layer of silicon dioxide. A film of a metal with a desired and proper work function is deposited on top of the silicon dioxide layer. The work function of the metal determines the threshold voltage required to turn on the p-channel MOSFET. A suitable and/or desired dielectric layer, such as silicon dioxide or silicon nitride, is deposited on top of the metal layer. The oxide/metal/dielectric tri-layer is then patterned by lithography to form a gate for a p-channel MOSFET. Another layer of a dielectric, such as silicon dioxide or silicon nitride, is deposited over the wafer. By anisotropic etching, spacers are formed at two sides of the gate. After proper cleaning, the surface areas of a source and drain are passivated with an atomic layer of a passivating agent. A second metal with a high work function is deposited as a film over the entire wafer. As previously described, high work-function metals for n-type silicon include nickel, palladium, gold, platinum, as examples. The second metal film is patterned (e.g., via lithography and etching) to form the source and drain electrodes. The final structure may go through one or more additional annealing steps as desired. Upon completion, the structure is ready for dicing, packaging, testing and use.

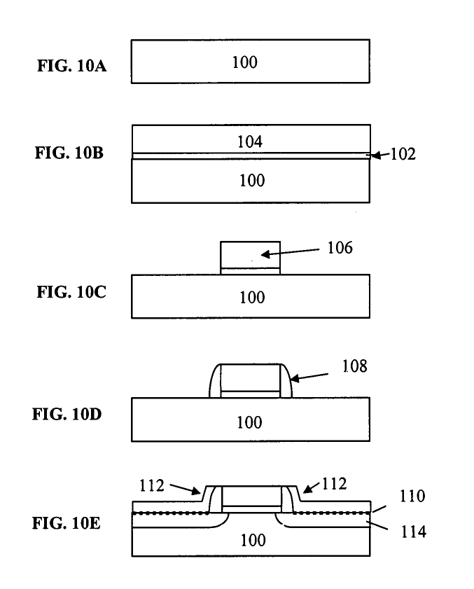

FIG. 10 schematically illustrates still another process flow for fabricating discrete silicon n-channel MOSFETs. With this example, a low-temperature oxidation process using ozone is incorporated, so the maximum temperature of the process flow is below 700° C. Referring to FIG. 10A, a process begins with substrate 100, which is a p-type silicon-containing substrate, wafer or other suitable substrate having a top surface and bottom surface, the top surface comprising a silicon-containing material. After proper cleaning, the top surface of substrate 100 is oxidized in ozone to form a layer of silicon dioxide 102 (FIG. 10B). The temperature of the oxidation process is below 700° C. A layer of a metal 104 with a proper work function is deposited on top of the silicon dioxide layer (FIG. 10B). The work function of the metal determines the threshold voltage required to turn on this n-channel MOSFET. The metal layer is patterned (e.g., by lithography) to form a gate 106 (FIG. 10C). A layer of a dielectric 108, such as silicon dioxide or silicon nitride, is deposited over the substrate. By anisotropic etching, as an example, the layer of dielectric is etched away, except at the two sides of the gate to form spacers (FIG. 10D). After proper cleaning, the surface areas of a source and drain are passivated with at least one atomic layer of a passivating agent 110. A film of a metal 112 with a low work function is deposited over the entire top surface (FIG. 10E). Low work-function metals for p-type silicon are those known to one of ordinary skill in the art, examples of which are described previously. Chemical mechanical polishing is performed to a point at which metal film 112 on top of the gate is removed (FIG. 10E). Chemical mechanical polishing electrically separates source, drain, and gate electrodes. The source and drain electrodes are further defined by patterning (e.g., via lithography). A region under the passivated portions formed by agent 110 becomes a n-type region 114. One or more additional annealing steps may also be performed, as desired. Upon completion, a final structure is ready for dicing, packaging, testing and use.

For p-channel MOSFETs, a process flow as described with FIG. 10 is modified starting with a substrate that is a n-type silicon-containing substrate/wafer having a top surface comprising silicon. After proper cleaning, the top surface of the substrate is oxidized in ozone to form a layer of silicon dioxide. A film of a metal with a proper work function is deposited on the silicon dioxide layer. The work function of the metal determines the threshold voltage required to turn on the p-channel MOSFET. The metal layer is patterned (e.g., by lithography) to form a gate for the p-channel MOSFET. A layer of a dielectric, such as silicon dioxide or silicon nitride, is deposited over the top of the substrate. By etching (e.g., anisotropic etching), spacers are formed at two sides of the gate. After proper cleaning, surface areas of the source and drain are passivated with at least one atomic layer of a passivating agent. A film of a metal with a high work function is deposited over the entire top surface. High work-function metals for n-type silicon include nickel, palladium, gold, platinum, as examples. Chemical mechanical polishing is performed to separate source, drain, and gate electrodes. One or more additional annealing steps may also be performed, as desired. Upon completion, a final structure is ready for dicing, packaging, testing and use.

As described herein are processes for low-temperature diffusion-less fabrication of structures and devices to provide an engineered substrate or device that is cost effective and easy to process. Features described include providing at least one atomic layer of a passivating agent onto a surface of a substrate, the surface comprising silicon. Passivation significantly minimizes electronic states bound to the silicon-containing surface (e.g., minimizes surface states). A metal layer is then formed on the passivated surface to form a p-n junction. Selection of the work function of the metal formed on the passivated surface further describes one or more functions of the device. When the silicon surface is n-type silicon, a metal with a large work function is deposited on the silicon surface. Deposition promotes modification of the surface into a p-type, thereby the structure is fabricated to behave like a p-n junction. When the silicon surface is p-type silicon, a metal with a small work function is deposited on the silicon surface. Deposition promotes modification of the surface into a n-type, thereby the structure is fabricated to behave like a p-n junction. Such structures may be further processed as described herein into suitable electronic devices, such as discrete silicon diodes and MOSFETs.

In the absence of diffusion or implantation followed by annealing, described herein are substrates, devices and methods of making that provide p-n junctions on silicon/silicon-containing substrates. As such, the substrates and devices formed herein and methods of fabricating such substrates and devices eliminate high-temperature diffusion and annealing processes, as compared with process flows typically used for manufacturing discrete electronic elements and devices. Energy conservation is associated with methods and process flows described herein.

While specific alternatives to steps of the invention have been described herein, additional alternatives not specifically disclosed but known in the art are intended to fall within the scope of the invention. Thus, it is understood that other applications of the present invention will be apparent to those skilled in the art upon reading the described embodiment and after consideration of the appended claims and drawing.

What is claimed is:

1. A method for forming one or more p-n junctions on a silicon-containing substrate comprising:
providing onto a surface of the substrate at least one atomic layer of a passivating agent to form a passivated surface, wherein the substrate is a semiconductor material of one conduction type;
depositing a metal on the passivated surface and forming a p-n junction, wherein a region of the passivated surface becomes a semiconductor material of another type.

2. The method of claim 1, wherein the passivating agent minimizes electronic states bound to the surface.

3. The method of claim 1, wherein the passivating agent is provided at one atomic layer.

4. The method of claim 1, wherein the substrate is selected from the group consisting of silicon, germanium, silicon-germanium, silicon-carbide, derivations and combinations thereof.

5. The method of claim 1, wherein the substrate is n-type, the metal has a large work function and at least a portion of the passivated surface is modified to p-type.

6. The method of claim 1, wherein the substrate is p-type, the metal has a small work function and at least a portion of the passivated surface is modified to n-type.

7. The method of claim 1, wherein the passivating agent is selected from the group consisting of a Group V, VI, or VII cogener, or hydrogen.

8. The method of claim 1, wherein the passivating agent is selected from the group consisting of sulfur, selenium, and tellurium.

9. The method of claim 1, wherein the method occurs at a temperature below 700 degrees Centigrade.

10. The method of claim 1, wherein the method further comprises a step of one or more of the group consisting of annealing, deposition, patterning, lithography, etching, oxidation, epitaxy and chemical mechanical polishing.

11. The method of claim 1, wherein the method is a process flow for making a discrete silicon device.

12. The method of claim 11, wherein the device is a diode.

13. The method of claim 1 1, wherein the device is a MOSFET.

14. The method of claim 1, wherein the method further comprises forming a source, gate and drain in a MOSFET.

15. The method of claim 1, wherein the region is under the deposited metal.

16. A method of forming one or more p-n junctions on a silicon-containing substrate by providing one or more n-type regions on a surface of a p-type silicon-containing substrate after providing a low work-function metal.

17. A method of forming one or more p-n junctions on a silicon-containing substrate by providing one or more p-type regions on a surface of a n-type silicon-containing substrate after providing a high work-function metal.

18. A method for forming one or more p-n junctions on a silicon-containing substrate comprising:
providing at least one atomic layer of a passivating agent onto a surface of a substrate, wherein the substrate is a semiconductor material of one conduction type;
applying a metal layer on the passivated surface to form a p-n junction, wherein a region of the passivated surface becomes a semiconductor material of another conduction type, wherein the region is under the metal.

19. A silicon containing device, wherein the device is a semiconductor material with one or more p-n junctions formed after passivation of a surface of the semiconductor material, wherein a region of the passivated surface is modified from one semiconductor conduction type to another conduction type.

20. The device of claim 19, wherein the device is a diode.

21. The device of claim 19, wherein the device is a MOSFET.

22. A method for forming a device having one or more p-n junctions, the method comprising:
providing onto a surface of a substrate at least one atomic layer of a passivating agent to form a passivated surface, wherein the substrate is a semiconductor material of one conduction type;
depositing one or more metallic electrodes on the passivated surface and forming p-n junctions at the metal-substrate interface, wherein a region under the interface becomes a semiconductor material of another conduction type.

23. The method of claim 22, wherein the passivating agent minimizes electronic states bound to the surface.

24. The method of claim 22, wherein the substrate is n-type, the metal has a large work function and the region of the interface is p-type.

25. The method of claim 22, wherein the substrate is p-type, the metal has a small work function and the region of the interface is n-type.

26. The method of claim 22, wherein the passivating agent is selected from the group consisting of a Group V, VI, or VII cogener, or hydrogen.

27. The method of claim 22, wherein the passivating agent is selected from the group consisting of sulfur, selenium, and tellurium.

28. The method of claim 22, wherein the method occurs at a temperature below 700 degrees Centigrade.

29. The method of claim 22, further comprising forming a bottom surface ohmic contact on the substrate.

30. The method of claim 22 further comprising annealing for formation of a silicide on the bottom surface of the substrate.

31. The method of claim 22, wherein the method provides a discrete silicon device.

32. The method of claim 22, wherein the device is a diode.

33. The method of claim 22, wherein the region is under the deposited metallic electrodes.

34. A device having one or more p-n junctions, wherein the device is a discrete diode with one or more p-n junctions formed after passivation of a surface of the semiconductor material, wherein a region of the passivated surface is modified from one semiconductor conduction type to another conduction type.

35. A device having one or more p-n junctions, wherein the device is a discrete MOSFET with one or more p-n junctions formed after passivation of a surface of the semiconductor material, wherein a region of the passivated surface is modified from one semiconductor conduction type to another conduction type.

36. A method for forming a device having one or more p-n junctions, the method comprising:
providing onto an etched surface of a substrate at least one atomic layer of a passivating agent to form a passivated surface, wherein the substrate is a semiconductor material of one conduction type, wherein one or more portions of the surface are layered with silicon dioxide, a first metal, and at least one dielectric layer;
depositing a second metal on the passivated surface and layered portions of the surface forming one or more p-n junction at the second metal-substrate interface, wherein a region under the interface becomes a semiconductor material of another conduction type.

37. The method of claim 36, wherein the method further comprises patterning the second metal.

38. The method of claim 36, wherein the method further comprises forming source and drain electrodes.

39. The method of claim 38, wherein a gate is electrically insulated from the source and drain.

40. The method of claim 36, wherein the substrate is n-type, the second metal has a large work function and the region of the interface is p-type.

41. The method of claim 36, wherein the substrate is p-type, the second metal has a small work function and the region of the interface is n-type.

42. The method of claim 36, wherein the method occurs at a temperature below 700 degrees Centigrade.
